(19) United States
(12) Patent Application Publication
(10) Pub. No.: US 2010/0068984 A1
(43) Pub. Date: Mar. 18, 2010

(54) Ventilation System and Method

(75) Inventor: Magnus Hansson, Bramhult (SE)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Wilhelmsen Callenberg Flakt AB, Molndal (SE)

(21) Appl. No.: 12/227,500

(22) PCT Filed: May 18, 2007
(86) PCT No.: PCT/SE2007/050336

§ 371 Date: Mar. 19, 2009

(30) Foreign Application Priority Data
May 19, 2006 (SE) 0601130-8

(51) Int. Cl. H05K 5/00; F24F 11/00

(52) U.S. Cl. 454/184; 454/239

(57) ABSTRACT

Ventilation system (10) comprising resistive heating means (12) for heating gas flowing through the ventilation system (10) and means that are arranged to provide a 5 controlled, continuously variable AC voltage/current to at least part of the resistive heating means (12) of the ventilation system (10) to modulate the power (24) being supplied thereto and to enable continuous regulation of the temperature of gas flowing through the ventilation system (10).

### TECHNICAL FIELD

The present invention concerns a ventilation system and a method for continuously regulating the temperature of gas flowing through a ventilation system.

### BACKGROUND OF THE INVENTION

Ventilation systems usually comprise resistive heating elements to heat gas passing through the ventilation system. A heater usually contains one or more resistive heating elements, such as electrically conductive wires or foils, which are connected to an electrical supply (usually a mains voltage of 230-480 V, 50-60 Hz). As electricity passes through said resistive heat elements, some energy is lost as heat due to the resistance of said elements. The more current that flows through the resistive heat elements, the more heat is generated.

If a resistive heater comprises a plurality of resistive heating elements, fuses and relays are used to connect different numbers of resistive heating elements in order to increase or decrease the heating capacity of the resistive heater (i.e. the amount of usable heat produced by the resistive heater). Such a solution means that the heating capacity of a resistive heater may only be adjusted in steps. Step-wise adjustment means that the heating capacity of the resistive heater can not be continuously controlled or optimised nor accurately matched to both specific and fluctuating demands, which limits the possibility of fine tuning processes while reducing energy costs. The more temperature adjustment options/steps a user has, the more electric components are required, which increases the size, cost and complexity of a ventilation system's temperature control unit.

### SUMMARY OF THE INVENTION

An object of the present invention is to provide a ventilation system with simple and cost-effective means to regulate the temperature of gas, such as air, flowing therethrough.

This object is achieved by a ventilation system comprising resistive heating means for heating gas flowing through (i.e. into, out of, or through at least part of) the ventilation system and means that are arranged to provide a controlled, continuously variable AC voltage/current to at least part of the resistive heating means of the ventilation system to modulate the power being supplied thereto and to enable continuous regulation of the temperature of gas flowing through the ventilation system.

According to an embodiment of the invention a variable frequency drive (VFD) or a matrix drive is arranged to modulate the power being supplied to at least part of the resistive heating means to enable continuous regulation of the temperature of gas flowing through the ventilation system.

The expression “resistive heating means” is intended to include heating elements that are arranged to primarily conduct heat and does not include inductive heating elements that are primarily arranged to induce heat electromagnetically. The resistive heating means may be arranged to heat said gas directly or indirectly, i.e. the resistive heating means may be in direct contact with said gas or they may be arranged to conduct heat to at least one another component, such as a metal tube surrounding said resistive heating means which is in direct contact with the said gas.

A VFD (which is also known as an adjustable speed drive, adjustable frequency drive (AFD), variable speed drive (VSD), AC drive, frequency drive and inverter drive) is an electronic controller that firstly converts an AC input power to a DC intermediate power, using a rectifier bridge for example. The DC intermediate power is then converted to a variable AC voltage output using pulse width modulation for example, whereby the inverter switches are used to divide the quasi-sinusoidal output waveform into a series of narrow voltage pulses and modulate the width of the pulses.

A matrix drive directly converts AC power at one frequency to AC power at another without an intermediate DC link. A matrix drive utilizes bi-directional high power semiconductor switches, which can be implemented utilizing back to back insulated gate bipolar transistors (IGBTs) and diodes.

The present invention utilizes the variable AC voltage/current output from the VFD or a matrix drive to supply power to one, some, or all of the resistive elements of resistive heating means and consequently utilizes a VFD or a matrix drive to vary the heating capacity of said resistive heating element(s).

A VFD or a matrix drive is able to vary the voltage (and not only the frequency) of its output signal and may therefore be arranged to provide continuous (i.e. step-less) temperature regulation in a more simple and cost effective way than conventional solutions. Step-less adjustment means that the heating capacity of resistive heating means can be continuously controlled and optimised and accurately matched to both specific and fluctuating demands, thereby allowing operators to fine tune processes while reducing energy costs. Step-less adjustment also means that a ventilation system's temperature control unit can be arranged to have a simpler and thus less expensive construction since only one, relatively simple electrical circuit is needed to regulate the temperature of gas flowing through a ventilation system.

It should be noted that conventional ventilation systems often comprise a VFD that is used to vary the rotational speed of an asynchronous motor that drives a component such as a fan or pump. Asynchronous motors are designed to run at a fixed rotational speed that is proportional to the number of poles and the power frequency (usually 50 Hz in Europe and 60 Hz in the USA). This means that the motor cannot produce such a large shaft horsepower at lower rotational speeds as compared to higher rotational speeds, since current surges through the motor's windings could quickly occur and result in overheating if the power output is disproportionally large in relation to the rotational speed. A VFD therefore has to be constructed to vary the output voltage in time with the output frequency varying. Small departures from a purely linear relationship between the supply voltage and frequency to a motor can be accomplished by most VFDs, for example, in order to compensate for non-linearities between the necessary power requirement on downward regulation of a pump motor for example so that the voltage is then decreased more than the frequency on downward regulation from nominal rotational speed.

The fact that a VFD regulates the voltage between 0 and 100% can be utilized to regulate the power from a resistive heater comprising heat resistant resistance wire that is heated by a voltage forcing a current through said wire that then becomes warm and emits its heat to passing air via an electrically insulated metal covering surrounding the wire. Since the electrical resistance in the wire is completely independent of the supply voltage (Ohm's law) for normally occurring frequencies less than 1000 Hz, a resistance wire connected to such a VFD will emit heat in proportion to the supply voltage independently of the supply frequency. Even though the VFD has a function that limits the voltage at low frequencies (due to the explanation given in the paragraph above) it does not affect the heat regulation of a space because the heat control itself merely makes a comparison between the actual and target value. If a room does not become warm enough the VFD just has to be set to a higher modulated frequency, which results in an increased output voltage and consequently a higher power supply to the air heater.

It is of course possible to provide voltage variation without variation of frequency with other devices in the form of different semiconductor components for example which can in different ways can supply a hearing wire with power and cause it to emit a variable heating capacity. Such devices are however substantially more expensive than VFDs since VFDs are more widely used than these devices that are consequently manufactured in much smaller quantities. Such devices must furthermore be used in conjunction with advanced electric filters to avoid EMC-interference to the surroundings and to the supply network. Such electric filters are standard components in VFDs. VFDs also standardly contain different types of current limiting protection, thus eliminating the need of a separate such component.

The present invention therefore makes use of existing technology in a completely new, advantageous and cost effective way.

According to an embodiment of the invention the ventilation system comprises a VFD that not only is arranged to modulate the power being supplied to at least part of the resistive heating means of the ventilation system, but that is also arranged to regulate the rotational speed of at least one electric motor, such as a motor that drives at least one component, such as fan or a pump, contained in the ventilation system or in its vicinity. A single component of a ventilation system may therefore be used in two different applications; namely to regulate the rotational speed of at least one motor and to regulate the heating capacity of at least part of at least one resistive heating means. In this way very economic heat regulation is achieved. It is even possible to have a system comprising a supply air fan, followed by an air heater and then an exit air fan to maintain pressure balance in the system whereby both fans and the air heater are driven by the same VFD.

According to an embodiment of the invention the ventilation system comprises a controller, such as a VFD- or matrix drive-controller, and means to provide said controller with a manually or automatically inputted target value, such as a desired cabin or room temperature, whereby the power being supplied to at least part of the resistive heating means is modulated in accordance with said manually or automatically inputted target value.

According to another embodiment of the invention the ventilation system comprises a sensor that is arranged to detect or monitor a parameter indicative of the heating capacity of the resistive heating means. Such a parameter may be the temperature of gas passing through the ventilation system, the temperature of part of the ventilation system or its surroundings, or the temperature or resistance of the resistive heating means for example. The sensor reading provides a controller with an actual value indicative of the heating capacity of the heating means. The power being supplied to at least part of the resistive heating means is then modulated so as to achieve or maintain a heating capacity that is in accordance with said manually or automatically inputted target value, i.e. the power being supplied is modulated so that the actual heating capacity corresponds to the target heating capacity.

According to a further embodiment of the invention the VFD or a matrix drive is arranged to supply the resistive heating means with a nominal voltage between 200-700 V_{AC}, 50-60 Hz.

The present invention also concerns a method for continuously regulating the temperature of gas flowing through a ventilation system comprising resistive heating means. The method comprises the step of providing a controlled, continuously variable AC voltage/current to at least part of the resistive heating means of the ventilation system to modulate the power being supplied thereto and to enable continuous regulation of the temperature of gas flowing through the ventilation system.

According to an embodiment of the invention the method also comprises the step of modulating the power being supplied to at least part of the resistive heating means using a VFD or a matrix drive.

According to an embodiment of the invention the method also comprises the step of providing a controller with a manually or automatically inputted target value and modulating the power being supplied to at least part of the resistive heating means in accordance with said target value.

According to another embodiment of the invention the method comprises the step of detecting or monitoring a parameter that is indicative of the heating capacity of the resistive heating means and modulating the power being supplied to at least part of the resistive heating means so as to achieve or maintain a heating capacity that is in accordance with said manually or automatically inputted target value.

The present invention further concerns a computer program product that comprises a computer program containing computer program code means arranged to cause a computer or a processor to execute at least one of the steps of a method according to any of the embodiments of the invention, stored on a computer-readable medium or a carrier wave and an electronic control unit (ECU) comprising such a computer program product. The ECU may contain a database containing pre-programmed heating/cooling schedules and/or may keep a log of information concerning a VFD or matrix drive power input and output and/or the performance of the resistive heating means to assist trouble-shooting and maintenance work.

The inventive ventilation system, method, computer program product and ECU are intended for use particularly but not exclusively on a sea-going vessel, such as a passenger ship, another movable or fixed offshore installation that is divided into a plurality of isolated cells, such as cabins, public spaces and/or non-public spaces such as, for example, engine rooms, storage spaces and/or lift shafts.

### BRIEF DESCRIPTION OF THE DRAWINGS

The present invention will hereinafter be further explained by means of non-limiting examples with reference to the appended figures where;

FIG. 1 shows schematically a ventilation system according to an embodiment of the invention,

FIG. 2 shows schematically a ventilation system according to another embodiment of the invention, and

FIG. 3 shows an electric circuit of a variable frequency drive according to an embodiment of the invention,

FIG. 4 shows an ideal switch equivalent circuit of a three-phase AC to three-phase AC frequency changer with matrix converter topology,

FIG. 5 shows a solid state switch realization of each pole of the switch of the matrix drive of FIG. 4, and

FIG. 6 is a flow diagram showing the steps carried of a method according to an embodiment of the invention.

It should be noted that the drawings have not been drawn to scale and that the dimensions of certain features have been exaggerated for the sake of clarity.

### DETAILED DESCRIPTION OF EMBODIMENTS

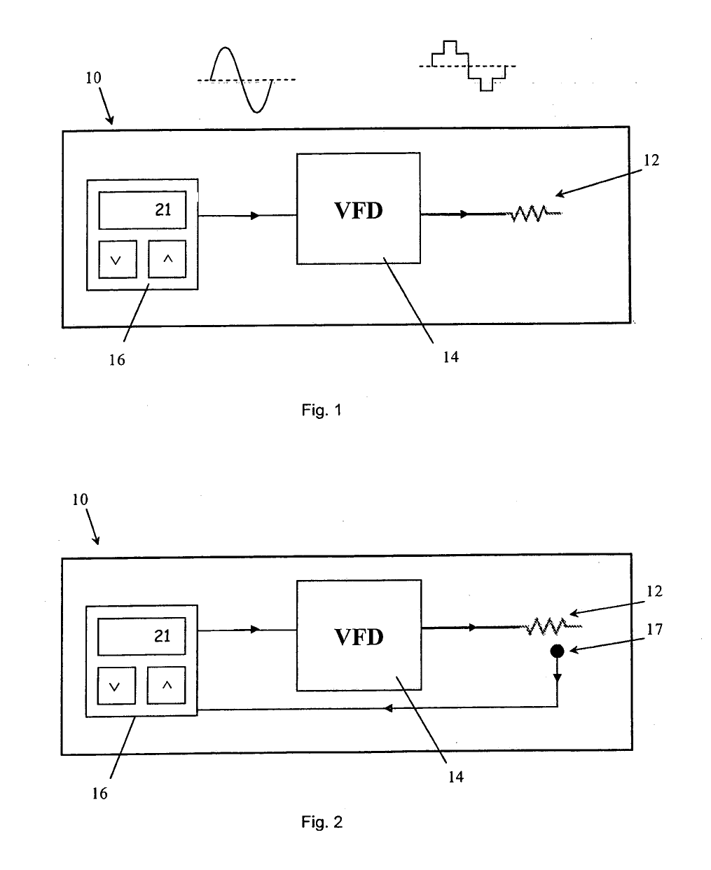

FIG. 1 shows a ventilation system 10 comprising a purely resistive heating element 12 consisting of one or more electrically conductive wires or foils located inside a stainless steel tube that heats up the supply air delivered to a cabin of a passenger ship. A VFD 14 supplies at least part of the resistive heating element 12 with electrical power and thereby controls the total heating capacity of the resistive heating element 12. A control panel on a VFD controller 16 presents various features that allow for automatic or manual control of the VFD 14 and includes display means, such as an LCD, to provide information concerning the operation of the VFD 14 and/or the resistive heating element 12.

In this example the VFD controller is provided with a target value only and not an actual value indicative of the heating capacity of the resistive heating element 12. The ventilation system 10 is calibrated so that the VFD controller supplies a pre-determined amount of power to the resistive heating element 12 depending on the magnitude of the target value.

Each VFD 14 in a ventilation system 10 can be arranged to regulate the heating capacity of one or more resistive heating elements 12. The inventive ventilation system 10 may therefore be used for conditioning, circulating and distributing air through several different isolated cells. Each isolated cell may be provided with individual resistive heating elements 12 so that a plurality of cells may be separately or simultaneously heated to individually selected temperatures to suit the needs or desires of their occupants. Each cell may also comprise thermostatic means to ensure that the ventilation system maintains each cell at a pre-determined temperature. Optionally each VFD 14 may also be arranged to regulate the rotational speed of one or more electric motors located inside the ventilation system 10 or in the vicinity thereof.

FIG. 2 shows another embodiment of a ventilation system 10 in which a temperature sensor 17, such as a thermocouple or an infrared camera, is placed in the vicinity of the resistive heating element 12 to measure the temperature of gas passing over the resistive hearing element 12 and provide the VFD controller 16 with information concerning the actual heating capacity of the resistive heating element 12. The actual temperature is compared to the target temperature and the power being supplied to the resistive heating element 12 is modulated until the actual temperature corresponds to the target temperature. The ventilation system therefore ensures that the VFD 14 is supplying the required to power the resistive heating element 12 and that the components of the ventilation system are working correctly.

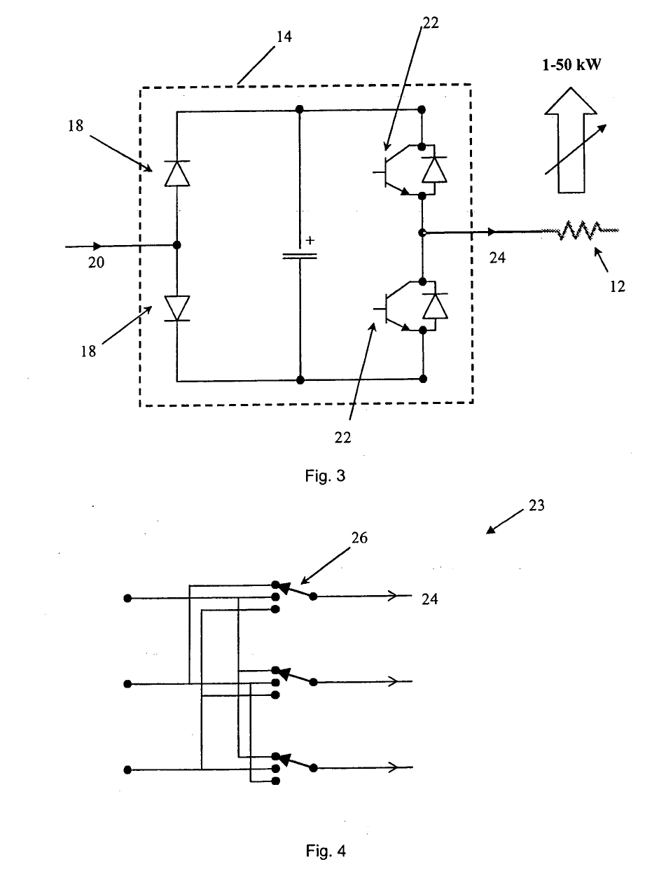

FIG. 3 shows an electric circuit of a variable frequency drive 14 configured for use with single-phase input power (for the sake of clarity), which may be used in carrying out the method according to an embodiment of the present invention. The input section of the VFD 14 contains two diodes 18 arranged as a rectifier bridge to convert AC input power 20 to DC intermediate power. The following section, the DC bus section, sees a fixed DC voltage and filters and smoothes out the waveform. The DC intermediate power is then converted to quasi-sinusoidal AC power using an inverter switching circuit comprising two insulated gate bipolar transistors (IGBTs) 22. The inverter switching circuit inverts the fixed DC voltage back to a variable AC voltage output by switching the DC bus on and off at specific intervals. This is called pulse width modulation. The variable AC voltage output 24 from the VFD (which can be 230-690 V_{AC} for example) is fed to at least part of the resistive heating element(s) 12 of a ventilation system and consequently varies the heating capacity of the heating element(s) 12 (from 1-50 kW for example as symbolized by the block arrow in FIG. 3).

The rectifier bridge of a VFD is usually a diode bridge but may also be a controlled rectifier circuit. The inverter switching circuit may comprise silicon-controlled rectifiers (SCRs) or semiconductor switches, such as IGBTs as shown in FIG. 3.

FIG. 4 schematically shows a matrix converter 23 which utilizes one pole and three throw switches 26 to directly convert an AC input voltage at one frequency to an AC output voltage at another frequency.

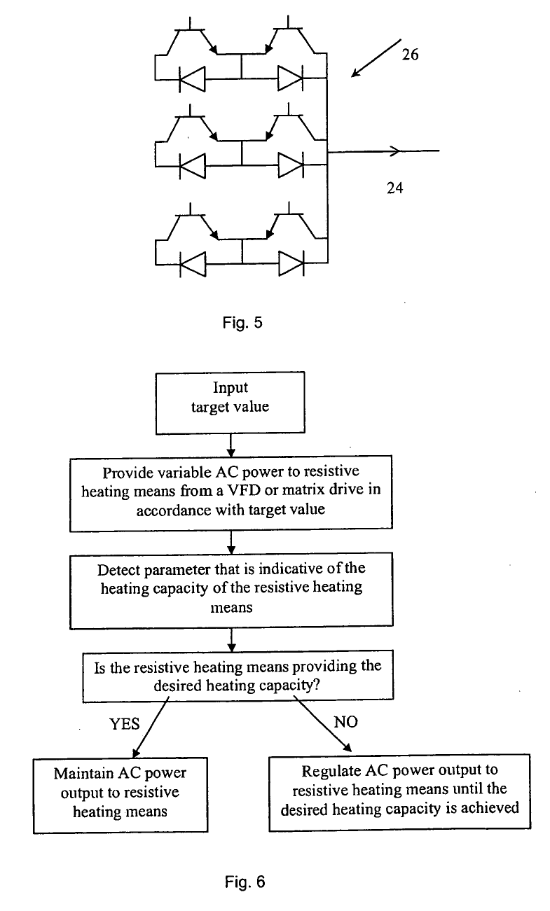

FIG. 5 shows back to back IGBTs and diodes may be used to implement the bi-directional high power semiconductor switches 26 shown in FIG. 4. The AC input from the three throw switches is converted to a variable AC voltage output 24. The variable AC voltage output 24 from the matrix drive is then fed to at least is fed to at least part of the resistive heating element(s) 12 of a ventilation system and consequently varies the heating capacity of the heating element(s) 12.

Due to the relatively high currents and voltages which these switches must handle, the semiconductor switches are relatively expensive and can limit the reliability of a converter system however a matrix drive avoids the need for a DC link capacitor that constitutes a life-limiting component of a converter and that contributes to the bulk of the converter.

FIG. 6 is a flow diagram of a method according to an embodiment of the invention, whereby at least some of the steps of the method may be executed by a computer or processor. The method comprises the steps of inputting a target value, such as a desired room temperature, into the controller of a VFD or matrix drive. AC power is then provided by the VFD or matrix drive to resistive heating means so that the resistive heating means will heat up air passing through a ventilation system to the desired temperature. The method also comprises the step of detecting or monitoring a parameter indicative of the heating capacity of the resistive heating means, using a temperature sensor for example. The AC power being supplied to the resistive heating means is continuously modulated until the desired room temperature has been achieved. Once the desired room temperature has been achieved, the AC power is continuously modulated to ensure that the desired room temperature is maintained.

Further modifications of the invention within the scope of the claims would be apparent to a skilled person. For example, the present invention is also suitable for the regulating the temperature of a liquid that is heated by the resistive heating means of the ventilation system.

1. Ventilation system (10) comprising resistive heating means (12) for heating gas flowing through the ventilation system (10), characterized in that it comprises means that are arranged to provide a controlled, continuously variable AC voltage/current to at least part of the resistive heating means (12) of the ventilation system (10) to modulate the power (24) being supplied thereto and to enable continuous regulation of the temperature of gas flowing through the ventilation system (10).

2. Ventilation system (10) according to claim 1, characterized in that it comprises a variable frequency drive (VFD) (14) or a matrix drive (23) that is arranged to modulate the power (24) being supplied to at least part of the resistive heating means (12) to enable continuous regulation of the temperature of gas flowing through the ventilation system (10).

3. Ventilation system (10) according to claim 1 or 2, characterized in that it comprises a controller (16) and means to provide said controller with a manually or automatically inputted target value whereby the power being supplied to at least part of the resistive heating means (12) is modulated in accordance with said manually or automatically inputted target value.

4. Ventilation system (10) according to claim 2, characterized in that it comprises a sensor (17) that is arranged to detect or monitor a parameter indicative of the heating capacity of the resistive heating means (12), such as the temperature of gas passing through the ventilation system (10) or the temperature of part of the ventilation system (10) or its surroundings, or the temperature or resistance of the resistive heating means (12), whereby the power (24) being supplied to at least part of the resistive heating means (12) is modulated so as to achieve or maintain a heating capacity that is in accordance with said manually or automatically inputted target value.

5. Ventilation system (10) according to any of claims 2-4, characterized in that the variable frequency drive (VFD) (14) is also arranged to regulate the rotational speed of at least one electric motor.

6. Ventilation system (10) according to any of claims 2-5, characterized in that the variable frequency drive (VFD) (14) or matrix drive (23) is arranged to supply the resistive heating means (12) with a nominal voltage between 200-700 V_{AC}, 50-60 Hz.

7. Method for continuously regulating the temperature of gas flowing through a ventilation system (10) comprising resistive heating means (12), characterized in that it comprises the step of providing a controlled, continuously variable AC voltage/current to at least part of the resistive heating means (12) of the ventilation system (10) to modulate the power (24) being supplied thereto and to enable continuous regulation of the temperature of gas flowing through the ventilation system (10).

8. Method according to claim 7, characterized in that it comprises the step of modulating the power (24) being supplied to at least part of the resistive heating means (12) using a variable frequency drive (VFD) (14) or a matrix drive (23).

9. Method according to claim 7 or 8, characterized in that it comprises the step of providing a controller (16) with a manually or automatically inputted target value and modulating the power (24) being supplied to at least part of the resistive heating means (12) in accordance with said target value.

10. Method according to any of claims 7-9, characterized in that it comprises the step of detecting or monitoring a parameter that is indicative of the heating capacity of the resistive heating means (12), such as the temperature of gas passing through the ventilation system (10) or the temperature of part of the ventilation system (10) or its surroundings, or the temperature or resistance of the resistive heating means (12), and modulating the power (24) being supplied to at least part of the resistive heating means (12) so as to achieve or maintain a heating capacity that is in accordance with said manually or automatically inputted target value.

11. Computer program product, characterized in that it comprises a computer program containing computer program code means arranged to cause a computer or a processor to execute at least one of the steps of a method according to any of claims 7-10, stored on a computer-readable medium or a carrier wave.

12. Electronic control unit (ECU) (16), characterized in that it comprises a computer program product according to claim 11.

13. Use of a ventilation system according to any of claims 1-6, a method according to any of claims 7-9, a computer program product according to claim 10 or an ECU according to claim 11 on a sea-going vessel, such as a passenger ship, another movable or fixed offshore installation that is divided into a plurality of isolated cells, such as cabins.
